(19) United States
(12) Patent Application Publication
(10) Pub. No.: US 2025/0051908 A1
(43) Pub. Date: Feb. 13, 2025

(54) LARGE GRAIN TUNGSTEN GROWTH IN FEATURES

(71) Applicant: Lam Research Corporation, Fremont, CA (US)

(72) Inventors: Kevin Qiwen CHEN, Fremont, CA (US); Yu PAN, San Jose, CA (US); Chan Myae Myae SOE, Santa Clara, CA (US); Esther JENG, Los Altos, CA (US); Juwen GAO, San Jose, CA (US)

(21) Appl. No.: 18/717,972

(22) PCT Filed: Dec. 9, 2022
(86) PCT No.: PCT/US2022/052437

§ 371 Date: Jun. 7, 2024

Related U.S. Application Data
(60) Provisional application No. 63/265,340, filed on Dec. 13, 2021.

(51) Int. Cl. C23C 16/04; C23C 16/02; C23C 16/36; C23C 16/455

(52) U.S. Cl. CPC C23C 16/045; C23C 16/0245; C23C 16/36; C23C 16/4554; C23C 16/45553

(57) ABSTRACT

Methods of filling a feature with large grain tungsten include deposition of a tungsten carbon nitride (WCN) or tungsten nitride (WN) film that lines the feature. The WCN or WN film may be treated. It provides a template for subsequent growth of large grain tungsten. The top of the feature is treated with nitrogen to inhibit nucleation, facilitating bottom-up growth. In some embodiments, single grain tungsten is grown from the bottom up. Methods of at least partially filling a feature with single grain tungsten include treatment of the feature. In some embodiments, single grain tungsten is grown without a liner layer in the feature.

### INCORPORATION BY REFERENCE

A PCT Request From is filed concurrently with this specification as part of the present application. Each application that the present application claims benefit of or priority to as identified in the concurrently filed PCT Request Form is incorporated by reference herein in its entirety and for all purposes.

### BACKGROUND

Tungsten (W) film deposition using chemical vapor deposition (CVD) techniques is an integral part of semiconductor fabrication processes. For example, tungsten films may be used as low resistivity electrical connections in the form of horizontal interconnects, vias between adjacent metal layers, and contacts between a first metal layer and the devices on a silicon substrate. In an example tungsten deposition process, a titanium nitride (TiN) barrier layer is deposited on a dielectric substrate, followed by deposition of a thin nucleation layer of tungsten film. Thereafter, the remainder of the tungsten film is deposited on the nucleation layer as a bulk layer.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect of the disclosure relates to a method including: providing a substrate including a feature having a feature top, a feature bottom and feature sidewalls; performing multiple cycles of an atomic layer deposition (ALD) process to deposit a tungsten carbon nitride (WCN) film to line the feature sidewalls; exposing the WCN film to a hydrogen-based plasma treatment; depositing a conformal tungsten (W) nucleation layer on the WCN film; selectively inhibiting deposition on the conformal tungsten nucleation layer near the feature top relative to the feature bottom; and filling feature with tungsten, wherein the tungsten is single-grain tungsten.

In some embodiments, the WCN film is at least 3 Angstroms thick. In some embodiments, the conformal nucleation layer is at least 10 Angstroms thick. In some embodiments, the conformal nucleation layer is at least 15 Angstroms thick.

In some embodiments, the method further includes cleaning the feature prior to depositing the WCN film.

In some embodiments, the hydrogen-based plasma treatment removes excess carbon and/or nitrogen from the WCN film.

In some embodiments, each cycle of the ALD process includes introducing a pulse of a nitrogen-containing organo-tungsten compound to adsorb on the feature sidewalls and exposing the substrate to a co-reactant to react with the adsorbed nitrogen-containing organo-tungsten compound.

In some such embodiments, exposing the substrate to a co-reactant includes exposing the substrate to a plasma.

In some such embodiments, the ALD process includes a first stage using a first plasma power, and a second stage using a second plasma power, the first plasma power being lower than the second plasma power.

In some embodiments, the co-reactant is at least one of H₂ and NH₃.

In some embodiments, the nitrogen-containing organo-tungsten compound is a tungsten bis(alkylimino)bis(alkylamino) compound.

In some embodiments, the organo-tungsten compound is selected from: W₂(NMe₂)₆, ethylcyclopentadienyl-dicarbonylnitrosyl-tungsten, methylcyclopentadienyl-dicarbonylnitrosyl-tungsten, and ethylcyclopentadienyl-tricarbonylhydridotungsten.

In some embodiments, the WCN film has between 30 and 80% (atomic) tungsten (W), between 3 and 50% (atomic) carbon (C), and between 1 and 60% (atomic) nitrogen (N).

Another aspect of the disclosure relates to a method including providing a substrate including a feature having a feature top, a feature bottom and feature sidewalls; performing multiple cycles of an atomic layer deposition (ALD) process to deposit a tungsten carbon nitride (WN) film to line the feature sidewalls; exposing the WN film to a hydrogen-based plasma treatment; depositing a conformal tungsten (W) nucleation layer on the WN film; selectively inhibiting deposition on the conformal tungsten nucleation layer near the feature top relative to the feature bottom; and filling feature with tungsten, wherein the tungsten is single-grain tungsten.

Another aspect of the disclosure relates to method including providing a substrate including a patterned structure, the patterned structure including a feature having a feature bottom and dielectric sidewalls, the feature having an exposed metal surface at the feature bottom, exposing the metal surface and dielectric sidewalls to a hydrogen-based plasma treatment; and at least partially filling feature with tungsten, wherein the tungsten is single-grain tungsten.

In some embodiments, at least partially filling the feature with tungsten includes depositing bulk tungsten by an atomic layer deposition (ALD) process. In some embodiments, bulk tungsten is deposited in the feature without first forming a liner layer or nucleation layer.

In some embodiments, the method further includes, after partially filling the feature with single grain tungsten, depositing a conformal adhesion layer over the exposed sidewalls and single grain tungsten. In some such embodiments, the method further includes depositing a metal layer on the conformal adhesion layer to complete fill of the feature.

In some embodiments, the method further includes, after partially filling the feature with single grain tungsten, exposing the feature to a hydrogen-based plasma treatment. In some such embodiments, the method further includes completing fill of the feature.

These and further aspects are described below with reference to the drawings.

### BRIEF DESCRIPTION OF THE DRAWINGS

FIG. 1 shows an example of a method of forming a filling a feature with large grain tungsten according to various embodiments.

FIGS. 2A-2F shows examples of cross-sectional schematic diagrams of a patterned feature after certain operations of the method of FIG. 1.

FIG. 3 shows an example of a method of depositing a tungsten carbon nitride (WCN) layer by atomic layer deposition (ALD) according to various embodiments.

FIG. 4A shows an example of a method of filling a feature with large grain tungsten according to various embodiments.

FIG. 4B shows an example of a method of completing feature fill and depositing an overburden layer according to various embodiments.

FIGS. 5A-5F shows examples of cross-sectional schematic diagrams of a patterned feature after certain operations of the methods of FIGS. 4A and 4B.

FIG. 6A shows tungsten growth on TEOS oxide after various pre-treatments.

FIG. 6B shows tungsten growth on PVD tungsten after various pre-treatments.

FIGS. 7 and 8 are schematic diagrams of examples of process tools for performing certain disclosed embodiments.

### DETAILED DESCRIPTION

Tungsten is widely used as a metal in front end of line (FEOL), middle of line (MOL), and back end of line (BEOL) features such as vias and trenches to form interconnects and lines. As metal pitches get smaller with each node, the resistance of these tungsten interconnects and lines can be a limiting factor in device performance. Increasing grain size and reducing the number of grains within the features lowers resistance.

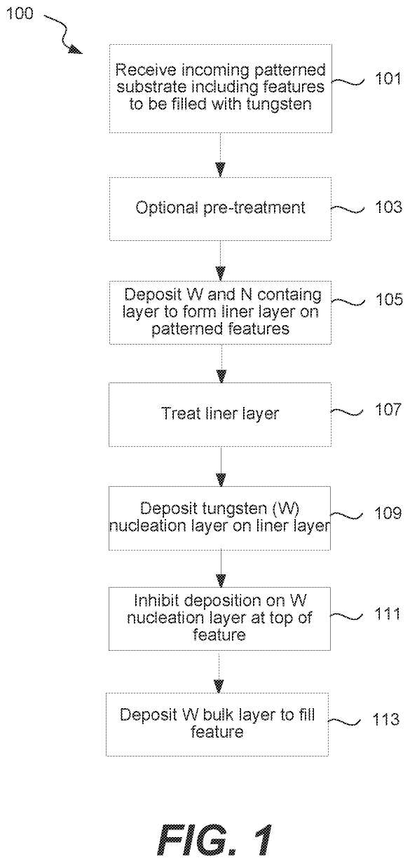

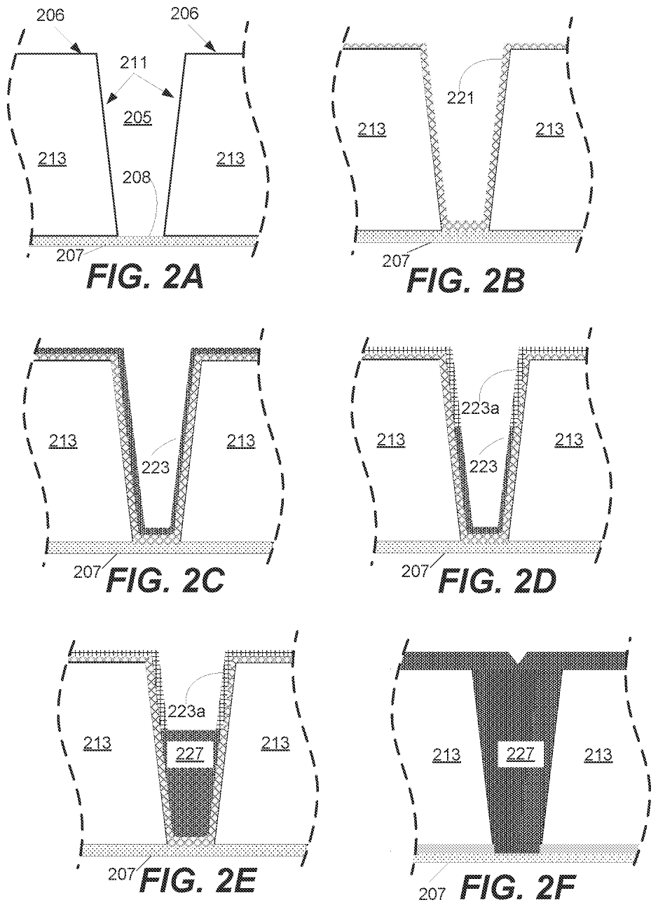

Provided herein are methods of filling features with tungsten that allow formation of large grains. In some embodiments, features are filled with single grain tungsten, with no grain boundaries. FIG. 1 shows an example of a method 100 of filling a feature with single grain tungsten according to various embodiments. First, a patterned substrate including patterned features is received at an operation 101. An example of a patterned feature is shown in FIG. 2A, with recess 205 formed a layer of oxide 213. The feature may be, for example, an etched feature that allows connection to an underlying metal 207 such as tungsten (W), molybdenum (Mo), copper (Cu), or cobalt (Co). The feature includes sidewalls surfaces 211, which are oxide or nitride, and a bottom surface 208, which is the surface of the metal 207. The metal surface may include a thin layer of metal oxide or impurity. If present, the metal oxide may be removed in a subsequent pre-treatment operation to leave an exposed metal surface. The patterned substrate also includes field surfaces 206, which are oxide or nitride, typically a silicon oxide such a doped or undoped silicon dioxide. The metal 207 may be part of any appropriate part of a partially fabricated semiconductor device, including a back end of line (BEOL) structure, a middle of the line (MOL) structure, or a source/drain (S/D) connection.

Returning to FIG. 1, an optional pre-treatment operation is performed in an operation 103. The pre-treatment may be plasma or thermal process and may use one or more gases such as hydrogen (H₂), nitrogen (N₂), ammonia (NH₃), and argon (Ar), alone or in combination. In some embodiments, for example, a remote plasma generated from H₂/Ar and/or a remote plasma generated from H₂/N₂ may be used. Operation 103 can clean the incoming surface and/or remove native oxides on the metal.

The optional treatment may be performed in the same chamber as the subsequent deposition or in a chamber connected to the deposition chamber under vacuum to prevent oxidation during transfer.

Next, deposition is performed to form a liner layer on the patterned features in an operation 105. The liner layer contains both tungsten and nitrogen. In some embodiments, it is WCN or tungsten nitride (WN). In embodiments in which WCN is deposited, operation 105 is described further below and involves an atomic layer deposition (ALD) process using an organometallic tungsten precursor. The thickness of the WCN layer may be as low as 3 Angstroms for templating a large grain tungsten layer. In some embodiments, it may be thicker, e.g., at least 5 Angstroms or at least 8 Angstroms for adhesion. Much thicker layers may be deposited in some embodiments, e.g., from 10 to 100 Angstroms for larger features in which the WCN layer acts as a barrier.

The WCN layer otherwise may be characterized by having good step coverage. For the purposes of this description, “step coverage” is defined as the ratio of the thickness on a field surface (e.g., field surfaces 206 in FIG. 2A) to the ratio on the sidewall (e.g., on sidewalls surfaces 211 in FIG. 2A). As described below, deposition on the oxide or nitride surfaces is conformal, such that the step coverage is about 1:1, e.g., ranging from about 1 to 1.3:1. A sidewall thickness may be measured near the feature bottom, for example, at a position corresponding to 80% of the feature depth as measured from a field surface to the bottom surface. The deposition may also be characterized by a uniform thickness on the sidewalls. For example, the thickness may vary on the sidewall only by no more than 20%, 10%, or 5%. An example of a patterned feature after deposition of the WCN layer is shown in FIG. 2B, with WCN layer 221 conformally coating the bottom surface 208, sidewall surfaces 211, and field surfaces 206.

While the WCN is generally uniformly thick on the sidewalls, the thickness on the bottom surface 208 may depend on the underlying metal. Deposition on cobalt may be selective to the dielectric such that it is thinner on the cobalt. Deposition on other metals such as tungsten may be selective to the dielectric but to a lesser degree than cobalt.

Once WCN layer is formed, it is treated in an operation 107. In some embodiments, treatment involves exposure to a hydrogen-based plasma. For example, the treatment may involve exposure to a remote or direct plasma generated from H₂/Ar. In some embodiments, the treatment removes excess carbon. In some embodiments, the treatment involves a thermal process with a reactive gas such as tungsten halide (e.g., tungsten hexafluoride (WF₆), tungsten hexachloride (WCl₆) or tungsten pentachloride (WCl₅)). In some such embodiments, a small amount of tungsten metal (W) may be deposited during the treatment. In some embodiments, the treatment may involve a high temperature anneal. For example, the treatment may involve heating the substrate to a temperature of 550° C. or higher. In some embodiments, operation 107 may be omitted. However, the treatment may help increase grain size of the subsequently deposited bulk tungsten layer.

At an operation 109, a tungsten (W) nucleation layer is deposited on the WCN layer. In various implementations, tungsten nucleation layer deposition can involve exposure to a tungsten-containing precursor and a reducing agent. In some implementations, pulses of tungsten-containing precursor can be alternated with pulses of one or more reducing agents, e.g., W/B/W/B/W/B or S+B/W/S+B/W, etc., where W represents a tungsten-containing precursor, S represents a silicon-containing reducing agent such as silane (SiH₄), and B represents a boron-containing reducing agent such as diborane (B₂H₆). In some implementations, a separate reducing agent may not be used, e.g., a tungsten-containing precursor may undergo thermal or plasma-assisted decomposition. Example thicknesses of a nucleation layer range from 5 to 30 Angstroms.

Tungsten nucleation layers generally have higher resistivity than the subsequently deposited bulk tungsten, so the nucleation layers are generally kept thin to keep their contribution to overall resistivity low. In some embodiments, operation 109 may be omitted with subsequent bulk deposition occurring on the WCN layer. However, while the bulk tungsten can be deposited on the WCN layer, it has been found that the presence of a nucleation layer increases grain size of the bulk layer. In some embodiments, the nucleation layer is at least 15 Angstroms to achieve large grain sizes.

An example of a patterned feature after deposition of a tungsten nucleation layer on the WCN layer is shown in FIG. 2C, with tungsten nucleation layer 223 conformally coating the WCN layer 221.

In an operation 111, an inhibition treatment is performed to inhibit deposition on the tungsten nucleation layer at the top of the feature. Operation 111 may be a plasma or a non-plasma, thermal treatment and can involve exposing the top of the feature to nitrogen species. In one example, a remote or direct plasma generated from a process gas containing nitrogen gas (N₂) is used. For example, a N₂/H₂ plasma may be used. In another example, ammonia (NH₃) gas is used in a non-plasma treatment. The treatment is performed such that the top of the feature is preferentially exposed to the nitrogen species with little or no exposure at the bottom of the feature. According to various embodiments, the treatment may extend into 10%, 20%, 30%, 40%, 50%, 60%, 70%, or 80% of the total feature depth. Plasma power, pressure, flowrate, and gas composition may be used to control the treatment depth.

The inhibition treatment treats the feature surface to inhibit subsequent tungsten nucleation at the treated surfaces. It can involve one or more of: deposition of an inhibition film, reaction of inhibition species with the tungsten nucleation layer to form a compound film, and adsorption of inhibition species. During the subsequent deposition operation, there is a nucleation delay on the inhibited portions of the underlying film relative to the non-or lesser-inhibited portions at the bottom of the feature. If a non-plasma operation, it may be purely thermal or activated by some other energy such as UV. In some embodiments, the operation 111 includes exposure to a metal precursor, which can be co-flowed with an inhibition gas or delivered in alternating pulses with it. FIG. 2D shows an example of a patterned feature after an inhibition treatment of a tungsten nucleation layer. The nucleation layer 223 includes inhibited portions 223a extending from the top of the feature. The remaining portion of the nucleation layer 223 remains uninhibited or inhibited to a lesser degree.

Once tungsten nucleation at the top of the feature is inhibited, gap fill may be performed in an operation 113. Gap fill involves deposition of a bulk tungsten layer in the feature and may be performed by chemical vapor deposition (CVD) or atomic layer deposition (ALD). Bulk deposition is described further below. Because of a nucleation delay on the inhibited portions 223a of the nucleation layer, the tungsten grows from the bottom surface 208 with little growth on the sidewall surfaces. FIG. 2E shows an example of a feature during the bulk deposition. The deposited tungsten 227 is shown growing from the bottom up. Bulk deposition continues until the feature is filled with tungsten as shown in the example of FIG. 2F.

Implementation of operations 103, 105, 107, and 111 all help induce large grain growth in patterned vias and trenches. For via features, a single grain of tungsten can be grown. Single grain growth may be achieved in features having lateral dimensions of up to 100 nm or so.

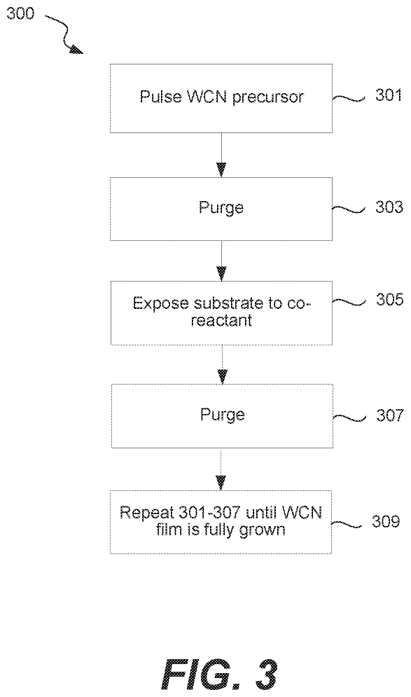

Deposition of the WCN layer may be performed in the same or a different chamber than the pre-treatment (if performed). If in a different chamber, the two chambers may be under a common vacuum to avoid exposure to air and possible oxide formation during transfer. In an ALD method, the substrate may be exposed in cycles such that the substrate is first exposed to a pulse of a suitable WCN precursor, then the precursor is purged, then the substrate is exposed to a pulse of a plasma containing a co-reactant, and then the co-reactant is purged, and such cycles may be repeated until a desired thickness of WCN is formed in the feature. The substrate temperature may be between about 100° C. and about 450° C., or between about 250° C. and about 400°° C. FIG. 3 shows an example of a method 300 of selectively depositing a WCN layer by ALD according to various embodiments. The method 300 may be performed during block 105 of FIG. 1, in some embodiments.

First, a WCN precursor is pulsed in an operation 301. The WCN precursor may be adsorbed onto the surface of the substrate, including on patterned features that include the metal surface of the bottom of the feature and oxide or nitride surfaces of the sidewalls. The WCN precursor may be a nitrogen-containing organo-tungsten compound, e.g., an organo-tungsten compound containing N-substituted amino and/or imino groups. Tungsten, carbon and nitrogen in the deposited film are supplied by the WCN precursor. In circumstances in which a greater nitrogen concentration is desired, additional nitrogen can be supplied by using a nitrogen-containing reducing agent such as ammonia (NH₃). In particular embodiments, a tungsten bis(alkylimino)bis(alkylamino) compound is used to deposit a WCN film. Such compounds have the following structure:

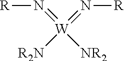

According to various embodiments, each R may be independently selected from methyl, ethyl, propyl, butyl and tert-butyl groups. These groups may be substituted or unsubstituted, though are typically unsubstituted. In a particular embodiment, the tungsten nitride precursor is bis(tert-butylimino) bis(dimethylamino) tungsten (W[N(C₄H₉)]₂[N(CH₃)₂]₂, which has the following structure:

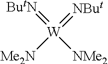

It should be noted that these imino and amino groups are also referred to as imido and amido groups in various publications, including the certain of the following referenced publications. For the purposes of this specification, imido and imino are used to refer to=NR groups and amido and amino are used to refer to−NR₂ groups. Non-selective deposition of tungsten nitride using bis(tertbutylimino) bis(dimethylamino) is described in the following publications: “Highly Conformal Thin Films of Tungsten Nitride Prepared by Atomic Layer Deposition from a Novel Precursor,” Becker et al., Chem. Mater., 2003, 15, 2969-2976 and “Diffusion barrier properties of tungsten nitride films grown by atomic layer deposition from bis(tertbutylimido)bis(dimethylamido)tungsten and ammonia,” Becker et al., Applied Physics Letters, 2003, 82(14), 2239-2241, which are hereby incorporated by reference. Non-selective deposition of tungsten nitride using bis(tert-butylimido)bis(tert-butylamido)tungsten is described in “Kinetic and Mechanistic Studies of the Chemical Vapor Deposition of Tungsten Nitride from Bis(Tertbutylimido)Bis(Tertbutylamido) tungsten,” Crane et al., J. Phys. Chem. B 2001, 105, 3549-3556 and “Tungsten nitride thin films prepared by MOCVD,” J. Mater. Res., 8(6), June 1993, 1353-1360. These references are incorporated by reference. Further examples include W₂(NMe₂)₆, ethylcyclopentadienyl-dicarbonylnitrosyl-tungsten (EDNOW), methylcyclopentadienyl-dicarbonylnitrosyl-tungsten (MDNOW), and ethylcyclopentadienyl-tricarbonylhydridotungsten (ETHW), available from Praxair. Next, a purge operation may be performed in an operation 303. A purge operation may involve flowing Ar or other inert gas and can result in excess (non-adsorbed) WCN precursor from being removed from the chamber. In some embodiments, a purge may not be performed.

The substrate is then exposed to a co-reactant in an operation 305. In some embodiments, this is in the form of a reducing plasma. Examples of reducing agents that may be used to generate a plasma include H₂ and NH₃. Other reducing agents may be used including N₂H₂. In some embodiments, both H₂ and NH₃ are employed, either together or in sequence. In some embodiments, a reducing agent is pulsed, and a plasma is ignited timed with the pulse. In some embodiments, the reducing agent (or multiple reducing agents) may be flowed throughout the process with a plasma ignited periodically. The plasma may be an inductively-coupled plasma (ICP) or a capacitively-coupled plasma (CCP). In may be a direct plasma or a remote plasma. In some embodiments, a thermal (non-plasma) ALD process is used. In such embodiments, other reducing agents may be employed such as boranes, silanes, and germanes, in addition to the reducing agents described above. In various embodiments, the WCN precursor and/or reducing agent are introduced into the chamber using a carrier gas, such as Ar or N₂. In some embodiments, a nitrogen-containing gas (such as N₂) may be used to incorporate nitrogen in the film. Such a gas may be pulsed with the reducing agent or reducing agents, or as an additional pulse.

The co-reactant reacts with the adsorbed WCN precursor to form a WCN film. The WCN film composition may vary, with for example, between 30 and 80% (atomic) W, between 3 and 50% (atomic) carbon, and between 1 and 60% (atomic) nitrogen. In alternate embodiments, there may be less than 1% (atomic) nitrogen present, such that the deposited barrier film is a tungsten carbide (WC) film instead of a WCN film. In alternate embodiments, there may be less than 1% (atomic) carbon present such that the deposited barrier film is a tungsten nitride (WN or WN₂) film.

Returning to FIG. 3, the chamber is purged again in an operation 307. This may be performed after the plasma (if used) is extinguished and can remove excess reactant and byproducts. In some embodiments, a purge may not be performed. Operations 301-307 may form a deposition cycle or part thereof that deposits WCN liner layer in the feature. Operations 301-307 may be repeated in sequence until the WCN film is fully grown in an operation 309.

If a direct plasma process is used in operation 305, the method 300 may involve an initial set of ALD cycles using a first plasma power and a second set of ALD cycles at second plasma power. This can minimize plasma-related damage to the dielectric surface. The first plasma power is lower than that of the second plasma power. In one example, a plasma power of between 100 and 300 W per station used in the first set of ALD cycles and between 400 and 600 W per station in the second set of ALD cycles. Per station power may be 100-400 W for the first plasma power and 400-1500 W for the second plasma power in some embodiments. For embodiments where only one plasma power is used, per station power may be 400-1500 W in some embodiments.

As noted above, in some embodiments, the method in FIG. 1 involves depositing a tungsten nitride (WN) liner layer rather than a WCN liner layer. Operations 101 and 103 may be performed as described above. Operation 105 involves deposition of a WN nitride layer.

Depositing a tungsten nitride layer may be performed by exposing the feature to sequential pulses of a tungsten precursor (e.g., WF₆), a reducing agent and a nitriding agent in a thermal (non-plasma) or a plasma ALD process. In certain embodiments of a thermal process, diborane (B₂H₆) is used as the reducing agent and ammonia (NH₃) is the nitriding agent. Boron-containing reducing agents such as B₂H₆ may be used rather than silicon-containing reducing agents such as silane (SiH₄) as the latter can result in significantly long nucleation delay for tungsten nitride deposition. Another example of a suitable nitriding agent is N₂H₄. In some embodiments, NH₃ may be co-flowed with a metal precursor.

In addition to WF₆, chlorine-containing tungsten precursors (WClₓ) such as tungsten pentachloride (WCl₅) and tungsten hexachloride (WCl₆) may be used. These precursors may be reduced to elemental tungsten (W) by reaction with reducing agents such as silane (SiH₄) and diborane (B₂H₆)

Examples of reducing agents can include boron-containing reducing agents including B₂H₆ and other boranes, silicon-containing reducing agents including SiH₄ and other silanes, hydrazines, and germanes.

In certain embodiments in which deposition involves a fluorine-containing precursor such as WF₆ the ratio of the metal precursor to B₂H₆ is at least 2.9:1. High WF₆:B₂H₆ ratio reduces fluorine attack. The mechanism by which this occurs is by reducing the number of sites on the surface on which the reducing agent adsorbs, thereby reducing the number of sites where WF₆ will react. Thus, although there is more fluorine species in the deposition chamber, fewer will react near the surface. In some embodiments, the reducing agent may be diluted with an inert gas.

Example substrate temperature ranges for deposition include 250° C. to 400° C., e.g., 250° C. to 350° C. In some embodiments, a relatively low temperature is used to improve step coverage. In some embodiments, a WN surface may be dehalogenated after deposition. Dehalogenating the surface can involve exposing the surface to a plasma generated from a hydrogen-containing gas such as H₂. In some embodiments, the plasma is generated from an Ar/H₂ mixture or a N₂/H₂ mixture. H radicals in the plasma react with fluorine impurities to form HF gas, which can be exhausted from the processing chamber.

Deposition of a tungsten nitride layer may involve plasma-enhanced deposition. In some embodiments, a remote or in-situ plasma generated from a nitrogen-containing gas such as N₂ may be used. Activated species such as atomic nitrogen or nitrogen ions may react with the metal precursor. According to various embodiments, one or more of the following sequences may be used to deposit a tungsten nitride layer.

B₂H₆ (or other reducing agent)/tungsten precursor/NH₃

B₂H₆ (or other reducing agent)/tungsten precursor/NH₃ +tungsten precursor

B₂H₆ (or other reducing agent)/tungsten precursor/N plasma species

In some embodiments, the reducing agent is ammonia (NH₃) or other nitrogen-containing reducing agent such hydrazine (N₂H₄). In such embodiments, the nitrogen-containing reducing agent may act as both a reducing agent and a nitridation agent. In such embodiments, the nitrogen-containing reducing agent may be co-flowed or pulsed with the tungsten precursor.

The amount of nitrogen in a tungsten nitride layer may vary. Accordingly, the term tungsten nitride does not suggest a particular ratio of metal to nitrogen. Similarly, WN may be used to indicate tungsten nitride of any appropriate W:N ratio.

Returning to FIG. 1, operation 107 may be performed as described above, with the treatment being performed on the WN layer. Operation 109 involves tungsten nucleation layer may be deposited on the WN layer. Operations 111 and 113 are performed as described above.

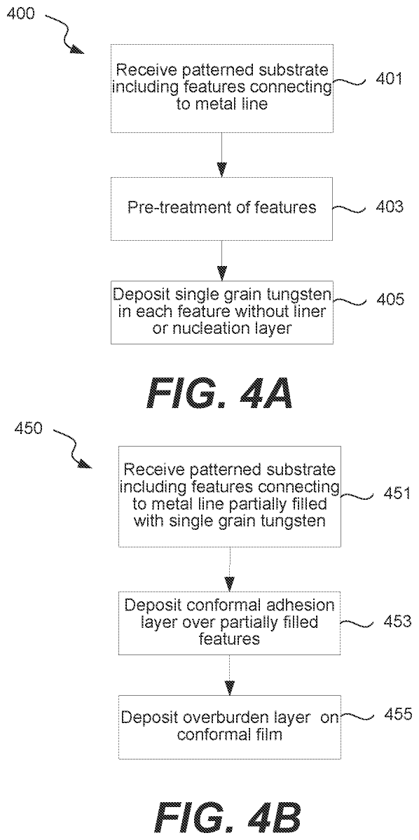

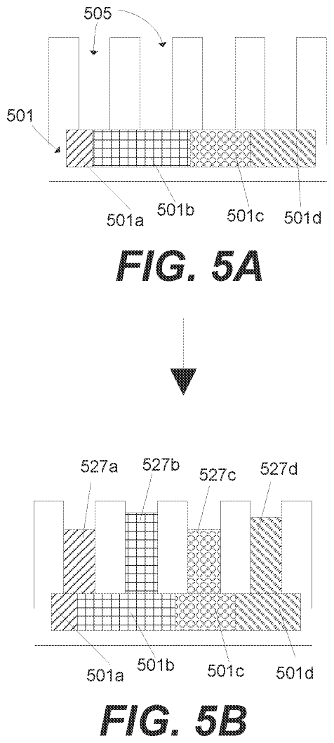

In some embodiments, single grain tungsten is grown from a metal line without a liner layer and/or nucleation layer. FIG. 4A shows a method of filling a feature with tungsten according to various embodiments. First, a patterned substrate including features connecting to a metal line is received at an operation 401. An example of a patterned feature is shown in FIG. 2A, as described above. The metal line may be W, Mo, Co, Cu, or other appropriate metal.

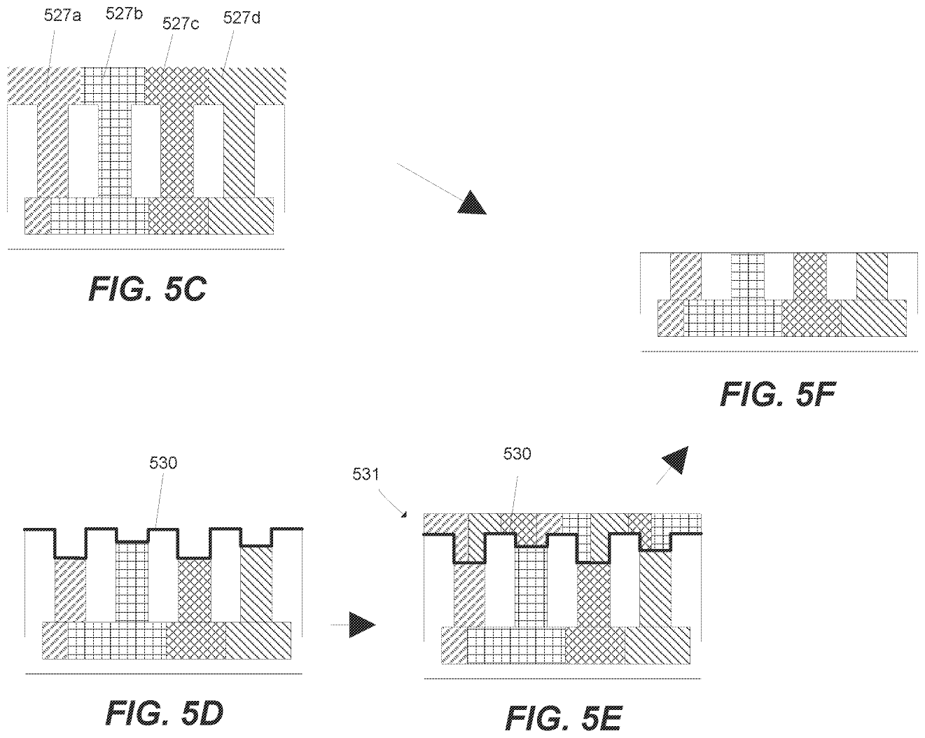

FIG. 5A shows another example of a patterned substrate including features 505 connecting to a metal line 501. The metal line 501 may be a multi-grain metal line. Regions 501a-501d of different metal grains are shown. As shown, a grain boundary may be part of a feature bottom. For example, the feature bottom of the leftmost feature includes a grain boundary between region 501a and region 501b.

Returning to FIG. 4, a pre-treatment operation is performed in an operation 403. The pre-treatment may be plasma or thermal process and may use one or more gases such as hydrogen (H₂), nitrogen (N₂), ammonia (NH₃), and argon (Ar), alone or in combination. In some embodiments, for example, a remote plasma generated from H₂/Ar and/or a remote plasma generated from H₂/N₂ may be used. Operation 403 can clean the incoming surface and/or remove native oxides on the metal line.

The pre-treatment may be performed in the same chamber as the subsequent deposition or in a chamber connected to the deposition chamber under vacuum to prevent oxidation during transfer.

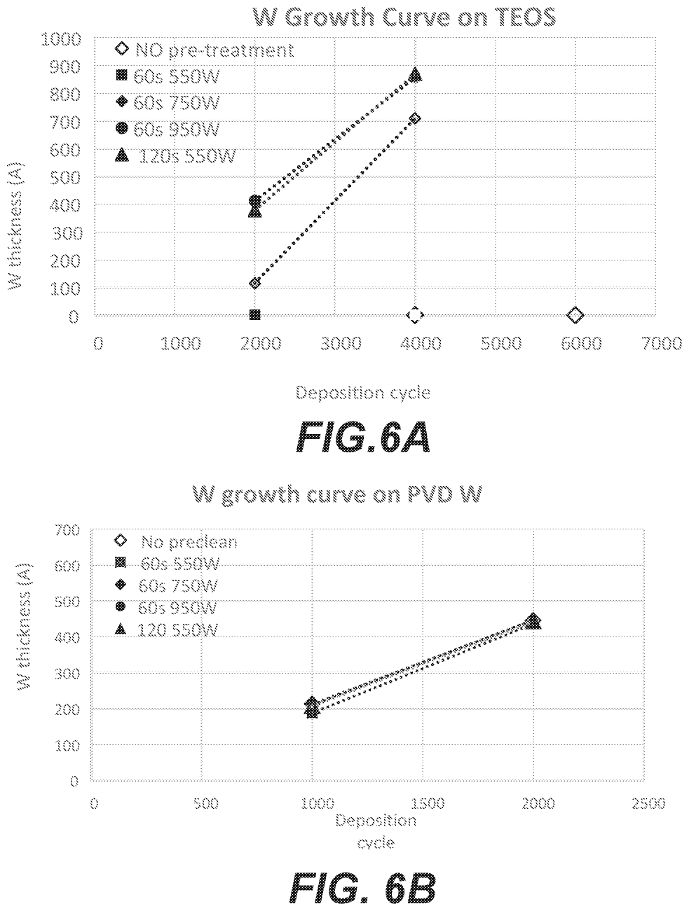

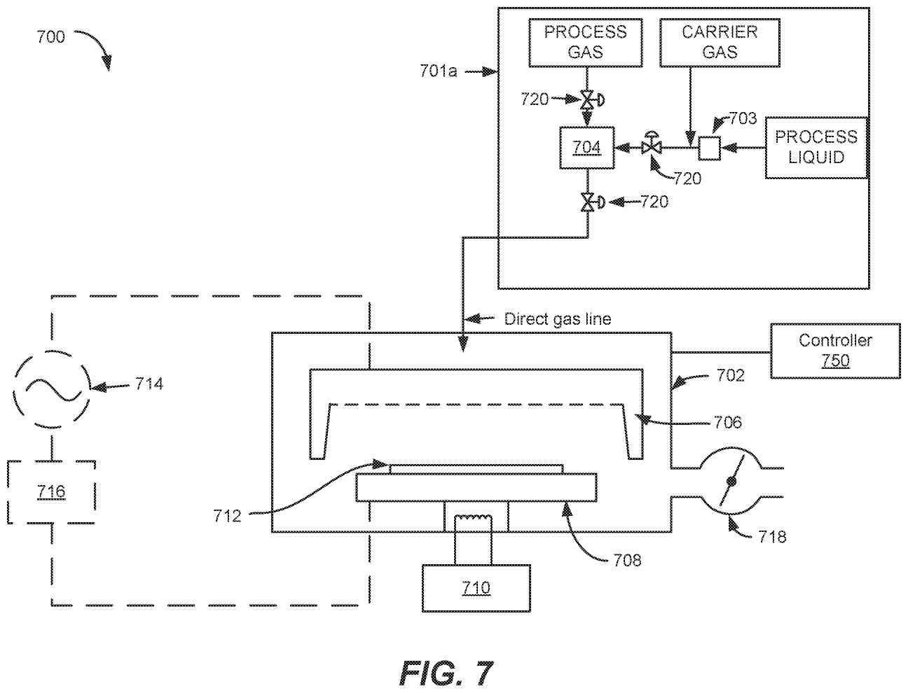

In addition to removing native oxides from the metal surfaces in the feature, operation 403 may also modulate the selectivity of the subsequent tungsten deposition on the metal line with respect to oxide or other dielectric surfaces That is, by increasing the pre-treatment time and/or strength, the selectivity to tungsten may be decreased. This effect is discussed further with respect to FIGS. 6A and 6B, below. Further, operation 403 may increase adhesion of the tungsten on the oxide or other dielectric surface. Deposition on and adhesion of the tungsten to dielectric can be important for deposition of an overburden layer and maintaining integrity of the tungsten interconnect during chemical mechanical planarization (CMP).

Next, in an operation 405, single grain tungsten is deposited in each feature. The tungsten in each feature is templated by the underlying metal. This is illustrated in FIG. 5B. Single grain 527a is templated by region 501a; single grain 527b is templated by region 501b, single grain 527c is templated by region 501c, and single grain 527d is templated by region 501d. The tungsten nucleates from one spot at the feature bottom, allowing a single grain to be formed. Thus, even if there are one or more grain boundaries at the feature bottom, single grain tungsten is formed within the feature.

Operation 405 involves ALD using a tungsten-containing precursor and H₂ as a reducing agent. Bulk deposition of W using ALD is discussed further below. During operation 405, the growth starts as pure bottom-up growth with the tungsten growing only from the underlying metal and not from the dielectric sidewalls. However, in some embodiments, as growth progresses the tungsten also grows from the sidewalls. This may help prevent holes from forming during growth and may improve adhesion. As discussed above and further below with respect to FIGS. 6A and 6B, the pre-treatment performed in operation 403 facilitates growth from sidewalls after an initial growth stage. In alternate embodiments, bulk deposition may use a CVD process.

In some embodiments, an inhibition treatment as described above may be implemented to facilitate bottom-up growth. In other embodiments, bottom-up growth is achieved by appropriately modulating the selectivity of the tungsten deposition without an inhibition operation.

In some embodiments, the single grain tungsten growth is continued to complete feature fill and grow an overburden layer The process may involve switching to CVD for the overburden to speed up the process. CVD may also be used to complete feature fill for throughput. The result of continuing bottom-up growth is shown in FIG. 5C, with each grain 527a-527d now filling a feature and providing an overburden.

In alternate embodiments, growth of the single grain tungsten in each feature may be stopped once all features are filled past a planarization point. A process 450 as described in FIG. 4B may be performed. The process begins with an operation 451 in which a patterned substrate including features partially filled with single grain tungsten is received. Receiving a substrate may involve simply maintaining a substrate that is already in station after deposition of the single grain tungsten or another process. In some embodiments, a substrate may be transferred to a new station or chamber for processing. FIG. 5B, described above, shows features partially filled with single grains 527a-517d.

Returning to FIG. 4B, a conformal adhesion layer is then deposited over the partially filled features in an operation 453. This layer can be used to improve adhesion of the tungsten to the surrounding dielectric during CMP. Lack of adhesion can be a problem during CMP and may occur particularly if the features are sparse. Examples of adhesion layers include WCN, W nucleation layers, and titanium nitride (TiN). Any layer that has good adhesion to dielectric and on which tungsten can grow may be used. The conformal adhesion layer may be removed during CMP. In such cases, it is not a part of the final device, so its electrical properties will not affect the final device. FIG. 5D shows a conformal adhesion layer 530 deposited the tungsten of the partially filled features, the feature sidewalls, and the field regions between the features.

Returning to FIG. 4B, an overburden layer is deposited over the conformal adhesion layer in an operation 455. Feature fill is completed during this operation. Because each feature is filled with single grain tungsten past the planarization point, the metal deposited in operation 455 will be removed and can be multi-grained. Typically, the metal is tungsten, though in some embodiments, a different sacrificial metal can be deposited. FIG. 5E shows a multi-grained layer 531 deposited on the conformal adhesion layer 530.

CMP can be performed after an overburden layer as in FIG. 5C or FIG. 5E is formed. FIG. 5F shows the filled features after CMP. Each feature is filled with single grain tungsten.

In an alternate embodiment, the method described above with respect to FIG. 4B may be modified by performing a plasma treatment instead of operation 453. The plasma treatment can modulate the selectivity of deposition of tungsten on the metal with respect to the dielectric. This can result in conformal growth without affecting the grain structure, such that the subsequent growth is single-grained.

### Nucleation Layer Deposition

In some implementations, the methods described herein involve deposition of a nucleation layer prior to deposition of a bulk layer. A nucleation layer is a thin conformal layer that facilitates subsequent deposition of bulk material thereon. The methods described herein are not limited to a particular method of nucleation layer deposition but include deposition of bulk film on nucleation layers formed by any method including ALD, CVD, and physical vapor deposition (PVD). Moreover, in certain implementations, bulk tungsten may be deposited directly in a feature without use of a nucleation layer, the WCN layer supporting bulk deposition. In some implementations, a bulk deposition process that does not use a nucleation layer may be performed.

In various implementations, nucleation layer deposition can involve exposure to a metal precursor as described above and a reducing agent. Examples of reducing agents can include boron-containing reducing agents including diborane (B₂H₆) and other boranes, silicon-containing reducing agents including silane (SiH₄) and other silanes, hydrazines, and germanes.

### Bulk Deposition

As described above, bulk deposition may be performed in an operation 113. In some implementations, bulk deposition can occur by a CVD process in which a reducing agent and a tungsten-containing precursor are flowed into a deposition chamber to deposit a bulk fill layer in the feature. An inert carrier gas may be used to deliver one or more of the reactant streams, which may or may not be pre-mixed. Unlike an ALD process, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted.

In some embodiments, bulk deposition is performed using as ALD processes in which a tungsten-containing precursor is alternated with a reducing agent. In such cases, a reducing agent such as H₂, which is a weaker reducing agent than a SiH₄ or B₂H₆ reducing agent using in nucleation layer deposition may be used.

While organo-tungsten precursors such as those described above with respect to WCN deposition can be used for tungsten nucleation layer and tungsten bulk deposition, tungsten halide precursors such as tungsten hexafluoride (WF₆), tungsten hexachloride (WCl₆), and tungsten pentachloride (WCl₅). These may be reduced by reaction with a reducing agent such as hydrogen (H₂), diborane (B₂H₆), silane (SiH₄), or germane (GeH₄).

### Inhibition of Tungsten Nucleation

An inhibition process may be performed as described above. Plasma inhibition processes involve exposure to a plasma generated from a nitrogen containing compound, such as N₂. Plasma power, chamber pressure, and/or process gases may be pulsed in some embodiments.

Thermal inhibition processes generally involve exposing the feature to a nitrogen-containing compound such as ammonia (NH₃) or hydrazine (N₂H₄) to non-conformally inhibit the feature near the feature opening. In some embodiments, the thermal inhibition processes are performed at temperatures ranging from 250° C. to 450°° C. At these temperatures, exposure of a previously formed tungsten or other layer to NH₃ results in an inhibition effect. Other potentially inhibiting chemistries such as nitrogen (N₂) or hydrogen (H₂) may be used for thermal inhibition at higher temperatures (e.g., 900° C.). For many applications, however, these high temperatures exceed the thermal budget. In addition to ammonia, other hydrogen-containing nitriding agents such as hydrazine may be used at lower temperatures appropriate for back end of line (BEOL) applications. During thermal inhibition, a metal precursor may be flowed with the inhibition gas or in alternating pulses with the gas.

Nitridation of a surface can passivate it. Subsequent deposition of tungsten on a nitrided surface is significantly delayed, compared to on a regular bulk tungsten film. In addition to nitrogen-containing species, fluorocarbons such as CF₄ or C₂F₈ may be used. However, in certain implementations, the inhibition species are fluorine-free to prevent etching during inhibition. Oxygen can also inhibit nucleation. However, in certain implementations, oxygen may be avoided.

In addition to the surfaces described above, nucleation may be inhibited on liner/barrier layers surfaces such WCN surfaces. Any chemistry that passivates these surfaces may be used. Inhibition chemistry can also be used to tune an inhibition profile, with different ratios of active inhibiting species used. For example, for inhibition of W surfaces, nitrogen may have a stronger inhibiting effect than hydrogen; adjusting the ratio of N₂ and H₂ gas in a forming gas can be used to tune a profile.

In certain implementations, the substrate can be heated up or cooled down before inhibition. A predetermined temperature for the substrate can be selected to induce a chemical reaction between the feature surface and inhibition species and/or promote adsorption of the inhibition species, as well as to control the rate of the reaction or adsorption. For example, a temperature may be selected to have high reaction rate such that more inhibition occurs near the gas source.

After inhibition, the inhibition effect may be modulated as described above. In the same or other embodiments, it may also be modulated by soaking it in a reducing agent or metal precursor, exposing it to a hydrogen-(H—) containing plasma, performing a thermal anneal, exposing it an air, which can reduce the inhibition effect.

One or more treatments to modulate the inhibition effect may also be performed before the inhibition treatment. For example, a reducing agent soak may be used to increase the inhibition effect.

### EXPERIMENTAL

Features were filled after deposition of a WCN liner layer and W nucleation layer using the following processes. A patterned structure of multiple vias was filled.

| | | | Post- | W | | | |
|---|---|---|---|---|---|---|---|
| Process | Pre-clean | WCN dep | treatment | nucleation | Inhibition | Bulk W | Result |
| 1 | Ar/H₂ | ALD | None | Thermal | Dilute N₂ | ALD | Single |
| | plasma | deposition | | ALD | Remote | process | grain |
| | N₂/H₂ | using | | deposition | plasma | using | within |
| | plasma | organo- | | using WF₆ | | WF₆ | most vias; |
| | | tungsten | | and B₂H₆ | | and H₂ | no |
| | | precursor | | | | | noticeable |
| | | and Ar/H₂ | | | | | seam |
| | | direct | | | | | |
| | | plasma | | | | | |
| 2 | Ar/H₂ | ALD | H₂/Ar | Thermal | Dilute N₂ | ALD | Single |
| | plasma | deposition | direct | ALD | Remote | process | grain |
| | N₂/H₂ | using | plasma | deposition | plasma | using | within |
| | plasma | organo- | | using WF₆ | | WF₆ | most vias; |
| | | tungsten | | and B₂H₆ | | and H₂ | no |
| | | precursor | | | | | noticeable |
| | | and Ar/H₂ | | | | | seam |
| | | direct | | | | | |
| | | plasma | | | | | |

Tungsten growth on metal (tungsten) and dielectric (tetraethyl orthosilicate (TEOS) oxide) without a nucleation or liner layer was compared for different pre-treatment operations using a H₂/Ar plasma. Results are shown in FIG. 6A and 6B. First, in FIG. 6A tungsten growth on TEOS oxide is shown for no pre-treatment, 60 second 550 W plasma pre-treatment, 60 second 750 W plasma pre-treatment, 60 second 950 W pre-treatment, and 120 second 550 W plasma pre-treatment. Direct high frequency plasma was used with a 1:1 volumetric ratio of H₂ and Ar. A chamber pressure of 0.5 to 1 Torr was used.

The results show that for no pre-treatment, no growth is observed. For 60 second 750 W plasma pre-treatment, 60 second 950 W pre-treatment, and 120 second 550 W plasma pre-treatment, growth is linear with respect to the number of deposition cycles. Plasma power can be used to tune the growth rate. For example, increasing plasma power from 750 W to 950 W increases the growth at 2000 cycles by 4 times for a 60 second treatment.

FIG. 6B shows that growth curves on PVD tungsten are similar for all treatments, including no treatment. Thus, the treatment conditions, and in particular, plasma power can be used to modulate the selectivity of tungsten deposition on metal with respect to dielectric surfaces.

### APPARATUS

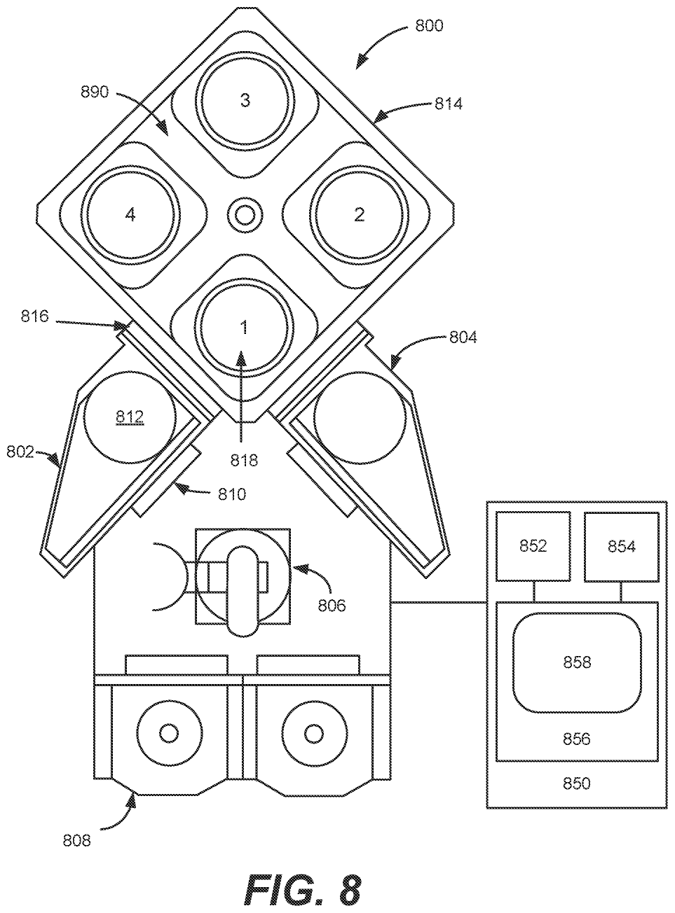

FIG. 7 depicts a schematic illustration of an embodiment of a process station 700 having a process chamber 702 for maintaining a low-pressure environment. A plurality of process stations may be included in a common low-pressure process tool environment. For example, FIG. 8 depicts an embodiment of a multi-station processing tool 800. In some embodiments, one or more hardware parameters of process station 700, including those discussed in detail below, may be adjusted programmatically by one or more computer controllers 750.

The process station 700 fluidly communicates with reactant delivery system 701a for delivering process gases to a distribution showerhead 706. Reactant delivery system 701a includes a mixing vessel 704 for blending and/or conditioning process gases, such as a WCN precursor-containing gas, hydrogen-containing gas, or nitrogen-containing gas, for delivery to showerhead 706. One or more mixing vessel inlet valves 720 may control introduction of process gases to mixing vessel 704. In various embodiments, deposition of a WCN film is performed in process station 700 and in some embodiments, other operations such as pre-treatment, post-treatment, W nucleation layer deposition, inhibition, and/or W bulk layer fill may be performed in the same or another station of the multi-station processing tool 800 as further described below with respect to FIG. 8. In other embodiments, the WCN deposition may be performed in a first chamber and W nucleation and bulk deposition performed in one or more additional chambers.

As an example, the embodiment of FIG. 7 includes a vaporization point 703 for vaporizing liquid reactant to be supplied to the mixing vessel 704. In some embodiments, vaporization point 703 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 704. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization Faster vaporization may reduce a length of piping downstream from vaporization point 4. In one scenario, a liquid injector may be mounted directly to mixing vessel 404. In another scenario, a liquid injector may be mounted directly to showerhead 706.

In some embodiments, one or more charge volumes may be disposed upstream of the showerhead 706 to accumulate and pressurize a process gas. A charge volume may be used to enhance step coverage of the WN or WCN film.

In some embodiments, a liquid flow controller (LFC) upstream of vaporization point 703 may be provided for controlling a mass flow of liquid for vaporization and delivery to process chamber 702. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 706 distributes process gases toward substrate 712. In the embodiment shown in FIG. 7, the substrate 712 is located beneath showerhead 706 and is shown resting on a pedestal 708. Showerhead 706 may have any suitable shape and may have any suitable number and arrangement of ports for distributing process gases to substrate 712.

In some embodiments, pedestal 708 may be raised or lowered to expose substrate 712 to a volume between the substrate 712 and the showerhead 706. In some embodiments, pedestal 708 may be temperature controlled via heater 710. Pedestal 708 may be set to any suitable temperature, such as between about 25° C. and about 650° C. during operations for performing various disclosed embodiments. It will be appreciated that, in some embodiments, pedestal height may be adjusted programmatically by a suitable computer controller 750. At the conclusion of a process phase, pedestal 708 may be lowered during another substrate transfer phase to allow removal of substrate 712 from pedestal 708.

In some embodiments, a position of showerhead 4 may be adjusted relative to pedestal 408 to vary a volume between the substrate 712 and the showerhead 706. Further, it will be appreciated that a vertical position of pedestal 708 and/or showerhead 706 may be varied by any suitable mechanism within the scope of the present disclosure. In some embodiments, pedestal 808 may include a rotational axis for rotating an orientation of substrate 712. It will be appreciated that, in some embodiments, one or more of these example adjustments may be performed programmatically by one or more suitable computer controllers 750. The computer controller 750 may include any of the features described below with respect to controller 850 of FIG. 8.

In some embodiments where plasma may be used as discussed above, showerhead 706 and pedestal 708 electrically communicate with a radio frequency (RF) power supply 714 and matching network 716 for powering a plasma. In some embodiments, the plasma energy may be controlled by controlling one or more of a process station pressure, a gas concentration, an RF source power, an RF source frequency, and a plasma power pulse timing. For example, RF power supply 714 and matching network 716 may be operated at any suitable power to form a plasma having a desired composition of ionic and radical species. Likewise, RF power supply 714 may provide RF power of any suitable frequency. In some embodiments, RF power supply 714 may be configured to control high-and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics Such monitors may include, but are not limited to, infrared (IR) monitors, acoustic monitors, and pressure transducers.

In some embodiments, instructions for a controller 750 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., the first precursor such as a WCN precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a second reactant gas such as H₂ or NH₃, instructions for modulating the flow rate of a carrier or purge gas, instructions for igniting a plasma, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 700 may be provided by butterfly valve 718. As shown in the embodiment of FIG. 7, butterfly valve 718 throttles a vacuum provided by a downstream vacuum pump (not shown). However, in some embodiments, pressure control of process station 700 may also be adjusted by varying a flow rate of one or more gases introduced to the process station 700.

As described above, one or more process stations may be included in a multi-station processing tool. FIG. 8 shows a schematic view of an embodiment of a multi-station processing tool 800 with an inbound load lock 802 and an outbound load lock 804, either or both of which may include a remote plasma source (not shown). A robot 806, at atmospheric pressure, is configured to move wafers from a cassette loaded through a pod 808 into inbound load lock 802 via an atmospheric port 810. A wafer (not shown) is placed by the robot 806 on a pedestal 812 in the inbound load lock 802, the atmospheric port 810 is closed, and the load lock inbound 802 is pumped down. Where the inbound load lock 802 includes a remote plasma source, the wafer may be exposed to a remote plasma treatment in the inbound load lock 802 prior to being introduced into a processing chamber 814. Further, the wafer also may be heated in the inbound load lock 802 as well, for example, to remove moisture and adsorbed gases. Next, a chamber transport port 816 to processing chamber 814 is opened, and another robot (not shown) places the wafer into the reactor on a pedestal of a first station shown in the reactor for processing. While the embodiment depicted in FIG. 8 includes load locks, it will be appreciated that, in some embodiments, direct entry of a wafer into a process station may be provided.

The depicted processing chamber 814 includes four process stations, numbered from 1 to 4 in the embodiment shown in FIG. 8. Each station has a heated pedestal (shown at 818 for station 1), and gas line inlets. It will be appreciated that in some embodiments, each process station may have different or multiple purposes. For example, in some embodiments, a process station may be switchable between an ALD and plasma-enhanced ALD process mode. In some embodiments, exposure to a deposition precursor and exposure to a second reactant and plasma are performed in the same station. Additionally or alternatively, in some embodiments, processing chamber 814 may include one or more matched pairs of ALD and plasma-enhanced ALD process stations. Further, exposure to a pre-treatment gas or plasma and an ALD process may occur in the same or different stations. While the depicted processing chamber 814 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 8 depicts an embodiment of a wafer handling system 890 for transferring wafers within processing chamber 814. In some embodiments, wafer handling system 890 may transfer wafers between various process stations and/or between a process station and a load lock. It will be appreciated that any suitable wafer handling system may be employed. Non-limiting examples include wafer carousels and wafer handling robots FIG. 8 also depicts an embodiment of a system controller 850 employed to control process conditions and hardware states of process tool 800. System controller 850 may include one or more memory devices 856, one or more mass storage devices 854, and one or more processors 852. Processor 852 may include a CPU or computer, analog, and/or digital input/output connections, stepper motor controller boards, etc.

In some embodiments, system controller 850 controls all of the activities of process tool 800. System controller 850 executes system control software 858 stored in mass storage device 854, loaded into memory device 856, and executed on processor 852. Alternatively, the control logic may be hard coded in the controller 850. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 558 may include instructions for controlling the timing, mixture of gases, gas flow rates, chamber and/or station pressure, chamber and/or station temperature, plasma exposure duration, UV radiation duration, wafer temperature, target power levels, RF power levels, substrate pedestal, chuck and/or susceptor position, and other parameters of a particular process performed by process tool 800. System control software 858 may be configured in any suitable way. For example, various process tool component subroutines or control objects may be written to control operation of the process tool components used to carry out various process tool processes. System control software 858 may be coded in any suitable computer readable programming language.

In some embodiments, system control software 858 may include input/output control (IOC) sequencing instructions for controlling the various parameters described above. Other computer software and/or programs stored on mass storage device 854 and/or memory device 856 associated with system controller 850 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 818 and to control the spacing between the substrate and other parts of process tool 800.

A process gas control program may include code for controlling gas composition (e.g., organo-tungsten compound-containing gases, co-reactant gases, gases for performing a pre-treatment, and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 550. The user interface may include a display screen, graphical software displays of the apparatus and/or process conditions, and user input devices such as pointing devices, keyboards, touch screens, microphones, etc.

In some embodiments, parameters adjusted by system controller 850 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 850 from various process tool sensors. The signals for controlling the process may be output on the analog and digital output connections of process tool 800. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 850 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 850 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 850.

In some implementations, the system controller 850 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 550, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 850 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 950 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 850, in some implementations, may be a part of or coupled to a computer that is integrated with, coupled to the system, otherwise networked to the system, or a combination thereof. For example, the system controller 850 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 950 receives instructions in the form of data, which specify parameters for each of the processing steps to be performed during one or more operations. It should be understood that the parameters may be specific to the type of process to be performed and the type of tool that the system controller 850 is configured to interface with or control. Thus as described above, the system controller 850 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

While FIGS. 7 and 8 provide examples of chambers and tools that may be used to perform the methods disclosed herein, various modifications may be made. These include the use of any CCP or ICP plasma generator or the use of a remote plasma generator. Further, in some embodiments, multiple single station and/or multi-station chambers may be connected to a transfer chamber in a common low-pressure environment, with all or subset of the operations described herein performed in the common low-pressure environment.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 850 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
providing a substrate comprising a patterned structure, the patterned structure including a feature having a feature bottom and dielectric sidewalls, the feature having an exposed metal surface at the feature bottom,
exposing the metal surface and dielectric sidewalls to a hydrogen-based plasma treatment; and
at least partially filling feature with tungsten, wherein the tungsten is single-grain tungsten.

2. The method of claim 1, wherein the at least partially filling the feature with tungsten comprises depositing bulk tungsten by an atomic layer deposition (ALD) process.

3. The method of claim 1, wherein the bulk tungsten is deposited in the feature without first forming a liner layer or nucleation layer.

4. The method of claim 1, further comprising, after partially filling the feature with single grain tungsten, depositing a conformal adhesion layer over the exposed sidewalls and single grain tungsten.

5. The method of claim S, further comprising depositing a metal layer on the conformal adhesion layer to complete fill of the feature.

6. The method of claim 1, further comprising, after partially filling the feature with single grain tungsten, exposing the feature to a hydrogen-based plasma treatment.

7. The method of claim 1, further comprising completing fill of the feature.

8. A method comprising:
providing a substrate comprising a feature having a feature top, a feature bottom and feature sidewalls;
performing multiple cycles of an atomic layer deposition (ALD) process to deposit a tungsten carbon nitride (WCN) film to line the feature sidewalls;
exposing the WCN film to a hydrogen-based plasma treatment;
depositing a conformal tungsten (W) nucleation layer on the WCN film;
selectively inhibiting deposition on the conformal tungsten nucleation layer near the feature top relative to the feature bottom; and
filling feature with tungsten, wherein the tungsten is single-grain tungsten.

9. The method of claim 8, wherein the WCN film is at least 3 Angstroms thick.

10. The method of claim 8, wherein the conformal nucleation layer is at least 10 Angstroms thick.

11. The method of claim 8, wherein the conformal nucleation layer is at least 15 Angstroms thick.

12. The method of claim 8, further comprising cleaning the feature prior to depositing the WCN film.

13. The method of claim 8, wherein the hydrogen-based plasma treatment removes excess carbon and/or nitrogen from the WCN film.

14. The method of claim 8, wherein each cycle of the ALD process comprises introducing a pulse of a nitrogen-containing organo-tungsten compound to adsorb on the feature sidewalls and exposing the substrate to a co-reactant to react with the adsorbed nitrogen-containing organo-tungsten compound.

15. The method of claim 14, wherein exposing the substrate to a co-reactant comprises exposing the substrate to a plasma.

16. The method of claim 15, wherein the ALD process comprises a first stage using a first plasma power, and a second stage using a second plasma power, the first plasma power being lower than the second plasma power.

17. The method of claim 14, wherein the co-reactant is at least one of H₂ and NH₃.

18. The method of claim 14, wherein the nitrogen-containing organo-tungsten compound is a tungsten bis(alkylimino)bis(alkylamino) compound.

19. The method of claim 14, wherein the organo-tungsten compound is selected from:
W₂(NMe₂)₆, ethylcyclopentadienyl-dicarbonylnitrosyl-tungsten, methylcyclopentadienyl-dicarbonylnitrosyl-tungsten, and ethylcyclopentadienyl-tricarbonylhydridotungsten.

20. The method of claim 8, wherein the WCN film has between 30 and 80% (atomic) tungsten (W), between 3 and 50% (atomic) carbon (C), and between 1 and 60% (atomic) nitrogen (N).

21. A method comprising:
providing a substrate comprising a feature having a feature top, a feature bottom and feature sidewalls;
performing multiple cycles of an atomic layer deposition (ALD) process to deposit a tungsten carbon nitride (WN) film to line the feature sidewalls;
exposing the WN film to a hydrogen-based plasma treatment;
depositing a conformal tungsten (W) nucleation layer on the WN film;
selectively inhibiting deposition on the conformal tungsten nucleation layer near the feature top relative to the feature bottom; and
filling feature with tungsten, wherein the tungsten is single-grain tungsten.
